(19) United States
(12) Patent Application Publication
(10) Pub. No.: US 2010/0002563 A1
(43) Pub. Date: Jan. 7, 2010

(54) MEDIA WITH TETRAGONALLY-STRAINED RECORDING LAYER HAVING IMPROVED SURFACE ROUGHNESS

(75) Inventors: Byong M. Kim, Fremont, CA (US); Jingwei Li, Fremont, CA (US); Pu Yu, Albany, CA (US); Donald E. Adams, Pleasanton, CA (US); Ying-Hao Chu, Albany, CA (US); Yevgeny V. Anoikin, Fremont, CA (US); Ramamoorthy Ramesh, Moraga, CA (US); Li-Peng Wang, San Jose, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 12/165,851

(22) Filed: Jul. 1, 2008

(51) Int. Cl. G11B 9/00; B32B 15/04; H01L 21/00

(52) U.S. Cl. 369/126; 428/212; 428/645; 428/621; 438/3; 257/E21.001; G9B/9

(57) ABSTRACT

A media for storing information comprises a substrate, a conductive layer formed over the substrate, and a ferroelectric layer epitaxially formed on the conductive layer. The ferroelectric layer includes an a-lattice constant that is substantially matched to an a-lattice constant of the conductive layer and an average c-lattice constant that is longer than an average c-lattice constant of a bulk-grown ferroelectric layer.

### BACKGROUND

Software developers continue to develop steadily more data intensive products, such as ever-more sophisticated, and graphic intensive applications and operating systems. As a result, higher capacity memory, both volatile and non-volatile, has been in persistent demand. Added to this demand is the need for capacity for storing data and media files, and the confluence of personal computing and consumer electronics in the form of portable media players (PMPs), personal digital assistants (PDAs), sophisticated mobile phones, and laptop computers, all of which place a premium on compactness and reliability.

Nearly every personal computer and server in use today contains one or more hard disk drives (HDD) for permanently storing frequently accessed data. Every mainframe and supercomputer is connected to hundreds of HDDs. Consumer electronic goods ranging from camcorders to digital data recorders use HDDs. While HDDs store large amounts of data, HDDs consume a great deal of power, require long access times, and require “spin-up” time on power-up. Further, HDD technology based on magnetic recording technology is approaching a physical limitation due to super paramagnetic phenomenon. Data storage devices based on scanning probe microscopy (SPM) techniques have been stusubstrated as future ultra-high density (>1Tbit/in2) systems. There is a need for techniques and structures to read and write to a ferroelectric media that facilitate desirable data bit transfer rates and areal densities.

### BRIEF DESCRIPTION OF THE DRAWINGS

Further details of the present invention are explained with the help of the attached drawings in which:

FIG. 1A is a perspective representation of a crystal of a ferroelectric material having a polarization.

FIG. 1B is a side representation of the crystal of FIG. 1A.

FIG. 2 is a cross-sectional side view of an information storage device including a plurality of tips extending from corresponding cantilevers toward a media.

FIG. 3 is a side view of a tip of the system of FIG. 2 arranged over a domain of a ferroelectric recording layer.

FIG. 4A is a simplified, partial side view of an embodiment of a media in accordance with the present invention illustrating a crystal structure of a portion of a ferroelectric recording layer and a conducting layer.

FIG. 4B is a simplified, partial side view of the media of FIG. 4A having a ferroelectric recording layer that is substantially lattice matched to the conducting layer.

FIG. 4C is a perspective representation of a crystal of the ferroelectric recording layer lattice matched to a crystal of the conducting material.

FIG. 5A is a perspective view of a surface of a ferroelectric film in accordance with an embodiment of the present invention formed by a step-flow epitaxy technique.

FIG. 5B is a series of resolved bit lines of the ferroelectric film of FIG. 5A defined by substantially straight edges.

FIG. 5C a readout result of bits formed in the ferroelectric film of FIG. 5A as measured using a radio frequency charge readout technique.

FIG. 5D is a perspective view of a surface of a ferroelectric film in accordance with an embodiment of the present invention formed by a layer-by-layer epitaxy technique.

FIG. 5E is a series of resolved bit lines of the ferroelectric film of FIG. 5D defined by substantially straight edges.

FIG. 5F a readout result of bits formed in the ferroelectric film of FIG. 5D as measured using an RF charge readout technique.

FIG. 6 is a simplified schematic flow diagram illustrating an embodiment of a method of forming a media in accordance with the present invention.

FIG. 7 is an x-ray diffraction rocking curve of the media of FIG. 4B.

FIG. 8 is a flow-chart of a method of binning a media in accordance with the present invention.

FIG. 9 is a flow-chart monitoring manufacturing of a media in a system for high density data storage in accordance with the present invention.

### DETAILED DESCRIPTION

Common reference numerals are used throughout the drawings and detailed description to indicate like elements; therefore, reference numerals used in a drawing may or may not be referenced in the detailed description specific to such drawing if the associated element is described elsewhere.

Ferroelectrics are members of a group of dielectrics that exhibit spontaneous polarization—i.e., polarization in the absence of an electric field. Permanent electric dipoles can exist in ferroelectric materials. Common ferroelectric materials include lead zirconate titanate (Pb[ZrₓTi₁₋ₓ]O₃ 0<x<1, also referred to herein as PZT). Taken as an example, PZT is a ceramic perovskite material that has a spontaneous polarization which can be reversed in the presence of an electric field.

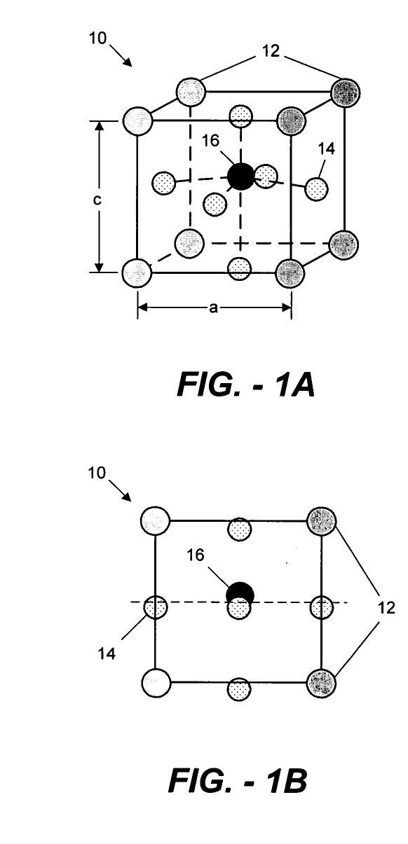

Referring to FIGS. 1A and 1B, a crystal of one form of PZT, lead titanate (PbTiO₃) is shown. Spontaneous polarization is a consequence of the positioning of the Pb²⁺, Ti⁴⁻, and 0²⁻ ions within the unit cell 10. The Pb²⁻ ions 12 are located at the corners of the unit cell 10, which is of tetragonal symmetry (a cube that has been elongated slightly in one direction). A permanent ionic dipole moment results from the relative displacements of the 0²⁻ and Ti⁴⁺ ions 14,16 from their symmetrical positions. The crystal shown has a dipole moment resulting from 0²⁻ ions 14 located near, but slightly below, the centers of each of the six faces, and a Ti⁴⁺ ion 16 displaced upward from the center of the unit cell 10.

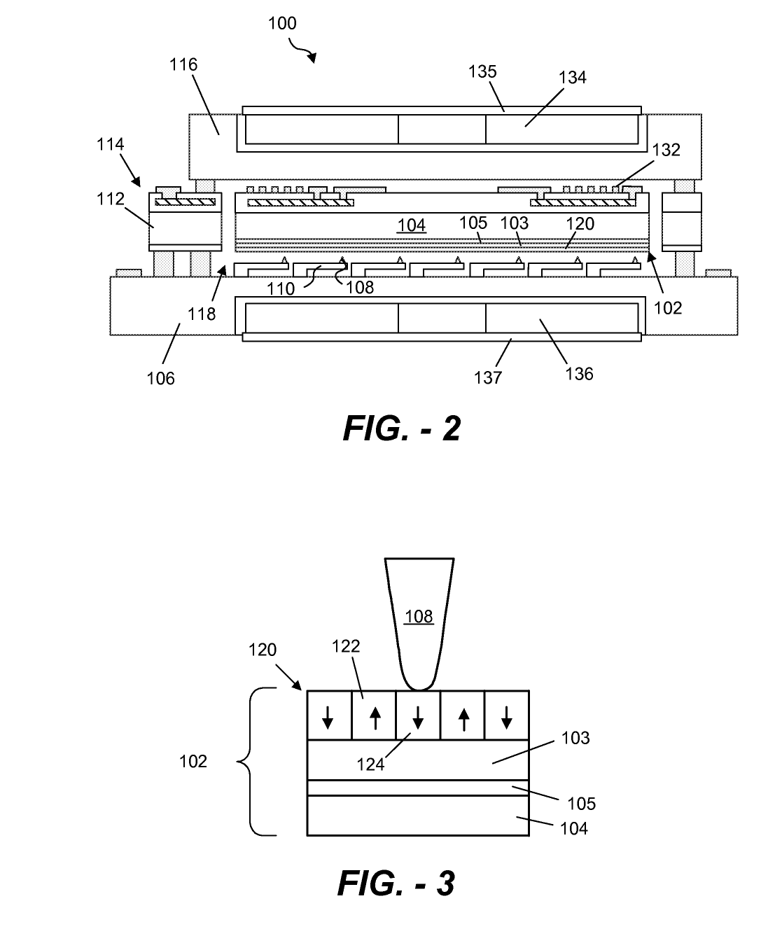

Ferroelectric films have been proposed as promising recording media, with a bit state corresponding to a spontaneous polarization direction of the media, wherein the spontaneous polarization direction is controllable by way of application of an electric field. FIG. 2 is a simplified cross-sectional diagram of a system for storing information 100 (also referred to herein as a memory device) with which embodiments of media and methods of forming media in accordance with the present invention can be used. Memory devices enabling potentially higher density storage relative to current ferromagnetic and solid state storage technology can include nanometer-scale heads such as contact probe tips, non-contact probe tips, and the like capable of one or both of reading and writing to a media. Memory devices for high density storage can include seek-and-scan probe (SSP) memory devices comprising cantilevers from which probe tips extend for communicating with a media. The cantilevers and probe tips can be implemented in a micro-electromechanical systems (MEMS) device with a plurality of read-write channels working in parallel. Probe tips are hereinafter referred to as tips and can comprise structures that communicate with a media in one or more of contact, near contact, and non-contact mode. A tip need not be a protruding structure. For example, in some embodiments, a tip can comprise a cantilever or a portion of the cantilever.

The memory device 100 comprises a tip substrate 106 arranged substantially parallel to a media 102. Cantilevers 110 extend from the tip substrate 106, and tips 108 extend from respective cantilevers 110 toward the surface of the media 102. A media (also referred to herein as a media stack) can comprise one or more layers of patterned and/or unpatterned ferroelectric films. A ferroelectric recording layer 120 of the media can achieve ultra high bit recording density because the thickness of a 180° domain wall in ferroelectric material is in the range of a few lattices (1-2 nm). The media 102 is associated with a media platform 104. A media substrate 114 comprises the media platform 104 suspended within a frame 112 by a plurality of suspension structures (e.g., flexures, not shown). The media platform 104 can be urged within the frame 112 by way of thermal actuators, piezoelectric actuators, voice coil motors, etc. As shown, the media platform 104 can be urged by electromagnetic motors comprising electrical traces 132 (also referred to herein as coils, although the electrical traces need not contain turns or loops) formed on the media platform and placed in a magnetic field so that controlled movement of the media platform 104 can be achieved when current is applied to the electrical traces 132. A magnetic field is generated outside of the media platform 104 by a first permanent magnet 134 and second permanent magnet 136 arranged so that the permanent magnets 134,136 roughly map the range of movement of the coils 132. The permanent magnets 134,136 can be fixedly connected with a rigid or semi-rigid structure such as a flux plate 135,137 formed from steel, or some other material for acting as a magnetic flux return path and containing magnetic flux. The media substrate 114 can be bonded with the tip substrate 106 and a cap 116 can be bonded with the media substrate 114 to seal the media platform 104 within a cavity 118. Optionally, nitrogen or some other passivation gas can be introduced and sealed in the cavity 118. In alternative embodiments, memory devices can be employed wherein a tip platform is urged relative to the media, or alternative wherein both the tip platform and media can be urged.

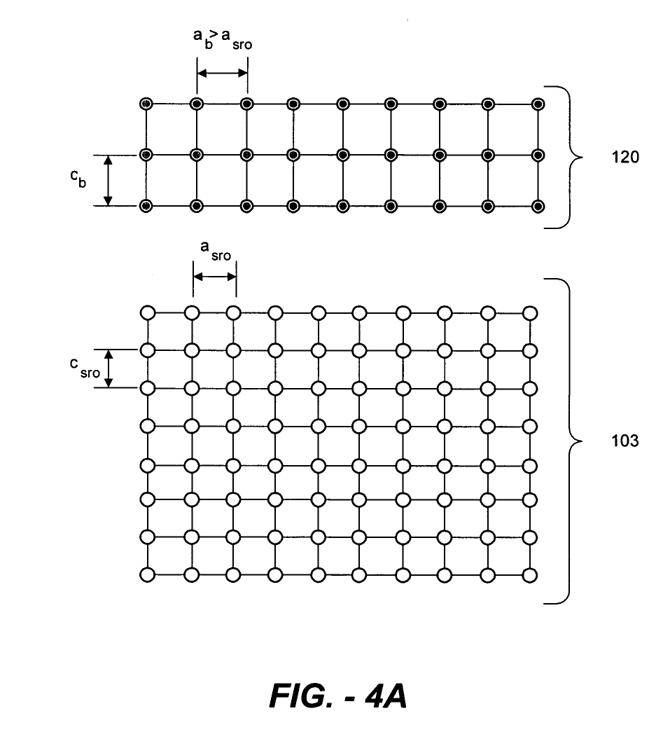

FIG. 3 is a partial cross-section showing a distal end of a tip 104 in contact or near contact with the media 102. The tip 108 can perform one or both of reading and writing. The media 102 comprises a ferroelectric recording layer 120 including domains having spontaneous polarization in an “UP” direction 122 and a “DOWN” direction 124. The ferroelectric recording layer 120 can comprise one or more layers of ferroelectric material and the one or more layers can include lattices repeating one or more times out-of-plane (i.e., along the c lattice constant perpendicular to a plane of the media). The media 102 further comprises a conductive layer 103 on which the recording layer 120 is formed so that the recording layer 120 is disposed between the tip 108 and the conductive layer 103, and a substrate 104 (or base layer 105, as shown) over which the conductive layer 103 is formed.

As a write tip, the tip is a conductive electrode that can apply a potential across the recording layer to selectably set—either “UP” or “DOWN”—the spontaneous polarization of a domain. As a read tip, multiple different techniques can be applied to determine the polarization of a domain. In an embodiment, a tip acts as an antenna, with charge coupling to the tip to induce a voltage that varies with polarization at a frequency determined by relative movement between the media and the tip. This readout technique is referred to herein as a radio frequency (RF) charge technique, and is described in detail in U.S. Ser. No. 11/688,806 entitled “SYSTEMS AND METHODS OF WRITING AND READING A FERRO-ELECTRIC MEDIA WITH A PROBE TIP,” incorporated herein by reference. In an alternative embodiment, a potential can be applied at a radio frequency (RF) across the recording layer below a switching level to induce expansion or contraction in the ferroelectric layer which in turn causes vibration of the tip. Tip vibration causes detectable variation in a capacitance of the cantilever. This readout technique is referred to hereinafter as piezoelectric force modulated charge (“PFMC”) sensing technique, and is described in detail in U.S. Ser. No. 12/030,101 entitled “METHOD AND DEVICE FOR DETECTING FERROELECTRIC POLARIZATION,” incorporated herein by reference.

In an embodiment of a media in accordance with the present invention, the ferroelectric recording layer 120 comprises a layer of PZT having lattices repeating out-of-plane. Formation of PZT over a conductive layer 103 can be controllably achieved when the PZT is formed on a crystal structure. Strontium ruthenate (Sr₂RuO₄, also referred to herein as SRO) is a well functioning member of a family of metallic conducting oxides with a perovskite type structure, making SRO a suitable material for use as a conductive layer 103. The perovskite type structure resembles PZT, providing a crystal structure suitable for forming PZT. The conductive layer 103 can be formed on a substrate and in an embodiment can have a thickness ranging from 50 to 100 nm. The SRO layer can be acceptably formed by applying one or more thin film techniques including techniques such as pulsed laser deposition (PLD), metal-oxide chemical vapor deposition (MOCVD), molecular beam epitaxy (MBE), and sputtering. The substrate facilitates crystalline growth of the conductive layer 103. Strontium titanate (SrTiO₃, also referred to herein as STO) is a high-K dielectric having a perovskite type structure with acceptable lattice matching to SRO. STO is suitable as a substrate; however, bulk STO may have an undesirably small surface area on which to form SRO (e.g., typically about 3 cm×10 cm). Further, bulk STO may be undesirably difficult to functionally integrate in a system having a structure as shown in FIG. 2. In a preferred embodiment, STO can be formed as a base layer 105 on a silicon substrate 104. STO can be epitaxially grown on a silicon wafer, for example, enabling fabrication of the media using processes associated with very-large-scale integration (VLSI) technology. STO can be grown using one or more known techniques such as PLD, MOCVD, MBE, and sputtering. STO is referred to hereinafter interchangeably as a base layer 105 formed on a substrate 104 and as a substrate (wherein a substrate can comprise STO or STO over silicon).

In alternative embodiments of a media in accordance with the present invention, a conductive layer can comprise one or more different crystal structure materials of various conductivity (doped or undoped), for example Perovskite materials such as yttrium-barium-copper-oxide (YBa₂Cu₃O₇, also referred to herein as YBCO), barium-strontium-titanate (Ba_{0.5}Sr_{0.5}TiO₃, also referred to herein as BST), strontium-bismuth-titanate (SrBi₄Ti₄O₁₅, also referred to herein as SBT), dysprosium scandate (DyScO3, also referred to herein as DSO), and others can be substituted for SRO. The conductive layer should have a lattice mismatch at an interface with the base layer or substrate (e.g., STO) sufficiently small such that pseudomorphic heteroepitaxial growth proceeds through the conductive layer.

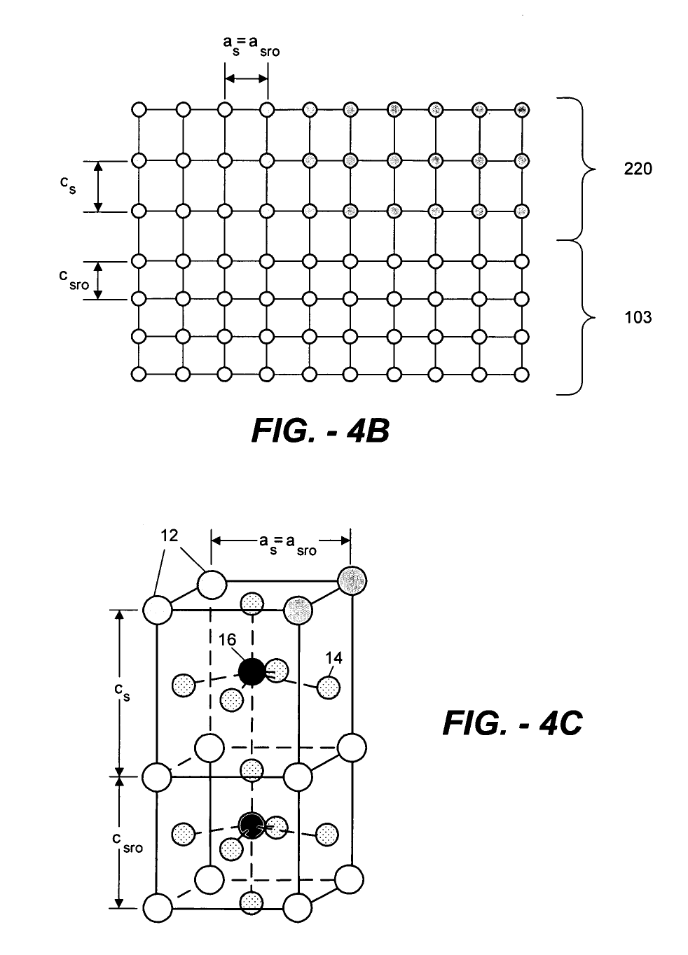

FIG. 4A is a simplified, partial side view of the recording layer 120 and the conductive layer 103 of FIG. 3 illustrating a crystal structure of a portion of the respective layers. A lattice constant (also referred to herein as a lattice parameter) is a constant distance between unit cells in the crystal lattice (and is substantially a distance between centers of metal cations—e.g., Pb and Sr). Crystal lattices generally have two lattice constants, a- and b-, corresponding to in-plane dimensions of the crystal lattice and one lattice constant, c-, corresponding to an out-of-plane dimension of the crystal lattice. However, the crystal structures of the recording layer 120 and conductive layer 103 of FIG. 4A have crystal lattices that are generally tetragonal in structure (i.e., having in-plane lattice constants of substantially equal length), so that a- and c-lattice constants can characterize the crystal structures. In epitaxial growth, the a-lattice constant can be considered a measure of the structural compatibility between different materials. Lattice constant matching can influence growth of thin layers of materials on other materials so that when a-lattice constants differ between materials, strains are introduced which prevent substantially defect-free epitaxial growth of layers beyond a critical thickness. Generally, thin layers of one crystal structure material can be grown on another crystal structure material when a lattice mismatch of less than 2% exists between the a-lattice constants of the two crystal structure materials. However, strain caused by lattice mismatch can become too great when thicker layers are grown or when the lattice constant exceeds 2%, causing dislocations in the material. STO is a suitable material for epitaxial growth on single crystal silicon because STO has an a-lattice constant of 0.3905 nm that when multiplied by 1.414 (i.e., the square root of two) is only slightly larger than the silicon a-lattice constant of 0.5431 nm. A thin layer of STO can be grown epitaxially on the (001)-oriented single-crystal silicon by aligning the (001) axis of STO with the (011) axis of silicon. Industry standard silicon wafers comprising (001)-oriented single crystal silicon are available that are atomically smooth, with root-mean-square (rms) roughness of about 0.1 nm. SRO is a conductor that has good lattice matching to STO and can be formed on STO having an a-lattice constant substantially matched to the STO a-lattice constant of 0.3905 nm. As can be seen in FIG. 4A, the a-lattice constant of 0.3905 for SRO (aₛᵣₒ) formed on STO is shorter than the a-lattice constant of 0.3935 for bulk PZT (a_{b}) such that the slight mismatch may cause dislocations to occur irregularly along the bulk PZT as the bulk PZT forms over SRO.

Embodiments of media and methods of forming media in accordance with the present invention include a recording layer comprising a ferroelectric material having a crystal structure grown in a strained state relative to a crystal structure of a bulk form of the ferroelectric material. It has been unexpectedly discovered that growing at least one type of ferroelectric material (PZT) so that a c-lattice constant of the ferroelectric material is longer than a c-lattice constant of a bulk form of the ferroelectric material can reduce surface roughness of the recording layer and dynamic friction on tips, thereby reducing tip wear and enabling increased scan speeds in systems for storing information. Referring to FIGS. 4B and 4C, the c-lattice constant of the ferroelectric material of the recording layer 220 is lengthened by pseudomorphically growing the ferroelectric material on an underlayer 103 (e.g., the conductive layer SRO) having a crystal structure with an a-lattice constant shorter than an a-lattice constant of a bulk form of the ferroelectric material. The crystal structure of the ferroelectric material can be substantially lattice-matched to the crystal structure of the underlayer 103, shortening the a-lattice constant of the ferroelectric material and causing the crystal structure of the ferroelectric material to be tetragonally strained. A conductive layer 103 well-matched to an STO base layer (105 in FIG. 3) or substrate (104 in FIG. 3) can cause tetragonal strain in a subsequently grown recording layer 220, but a lattice mismatch between the recording layer 220 and conductive layer 103 should be made sufficiently small to ensure that generally pseudomorphic heteroepitaxial growth proceeds. The crystal structure of the recording layer 220 placed under tetragonal strain is caused to lengthen out-of-plane (i.e., the c-lattice constant is lengthened).

Heteroepitaxy of PZT on SRO goes by pseudomorphic growth until critical thickness (approximately 30 nm). Above critical thickness, excess energy is reduced by relieving strain. It has been observed that in PZT formed over SRO strain is relieved by interfacial misfit dislocations that form as cross-hatches. Cross-hatches can appear on the surface of the recording layer by extension of the strain field to the surface and/or by gliding of a dislocation to the surface. It is believed that cross-hatches on the surface are evidence that the PZT is undergoing acceptably pseudomorphic growth. As mentioned above, pseudomorphic growth without cross-hatches is possible if growth terminates at or prior to critical thickness. Cross-hatch line density on the surface has been observed at about ten lines or less per (10 μm)² surface area, an acceptable result that does not negatively affect domain formation in the recording layer. However, a cross-hatch line density of five lines or less per (10 μm)² surface area can be preferably achieved by applying methods of forming such media in accordance with the present invention. Cross-hatch line height (i.e., peak-to-valley height variation) in PZT has been achieved at two monolayers or less with an rms surface roughness less than 0.3 nm. A PZT surface with less than 0.3 nm rms surface roughness can be considered atomically smooth, enabling terabit scale write and/or read with acceptable bit-error distribution. Further, it has been observed that cross-hatch line height of less than one monolayer with rms roughness less than 0.15 nm can be preferably achieved by applying methods of forming such media in accordance with the present invention.

Embodiments of media in accordance with the present invention can comprise a recording layer of tetragonally strained 20/80 PZT (i.e., 20% Zr and 80% Ti) formed over the conductive layer having a thickness to roughly 60 nm, while in a preferred embodiment the PZT is about 30 nm in thickness. It has been demonstrated that such a recording layer can enable ferroelectric domains (representing data bits) at least as small as 15 nm in diameter to be formed. A 20/80 PZT film can be acceptably formed by applying one or more of multiple different thin film techniques including PLD, MOCVD, MBE and sputtering. A PZT film formed over SRO and having good surface characteristics has been observed having a c-lattice constant, cₛ, around 0.4239 nm and above, the PZT film being tetragonally strained relative to a bulk form of 20/80 PZT, which has an unstrained c-lattice constant, c_{b}, of about 0.4148 nm. It has been unexpectedly observed that PZT surface smoothness generally improves as the c-lattice constant increases, and in a preferred embodiment a c-lattice constant of about 0.4268 nm is achieved. While c-lattice constants having specific values have been referred to herein, embodiments of media in accordance with the present invention are not intended to be limited to ferroelectric materials having a specific c-lattice constant or range of c-lattice constants, but rather are intended to apply to recording layers comprising ferroelectric materials that are tetragonally strained along a substantial portion of the recording layer.

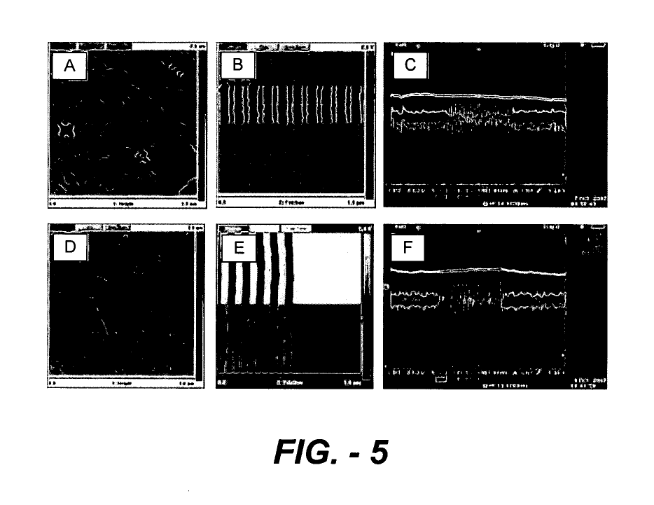

Referring to FIG. 5A, a first example of a PZT recording layer having a c-lattice constant of substantially 0.42395 nm is shown having one type of atomically smooth topology comprising monolayer height step terraces characteristics of step-flow epitaxy. The surface roughness on the recording layer is 0.27 nm nominal over a 1 μm² surface area. An AFM based read/write on the PZT recording layer demonstrates ferroelectric bits of 100 nm pitch lines of virtually straight edges (FIG. 5B). Referring to FIG. 5C, an RF charge readout technique applied with a tip contact force of about 1.5 μN and a tip scan speed 814 μm/s resolves the bits individually with a signal-to-baseline ratio about 2.

Referring to FIG. 5D, a second example of a PZT recording layer having a c-lattice constant of substantially 0.42395 nm is shown having another type of atomically smooth topology comprising monolayer height flat regions characteristics of layer-by-layer epitaxy. The surface roughness on the recording layer is 0.29 nm nominal over a 1 μm² surface area. As above, an AFM based read/write on the PZT recording layer demonstrates ferroelectric bits of 100 nm pitch lines of virtually straight edges (FIG. 5E). Likewise, referring to FIG. 5C, an RF charge readout technique applied under similar conditions as above resolves the bits individually with a signal-to-baseline ratio about 2.

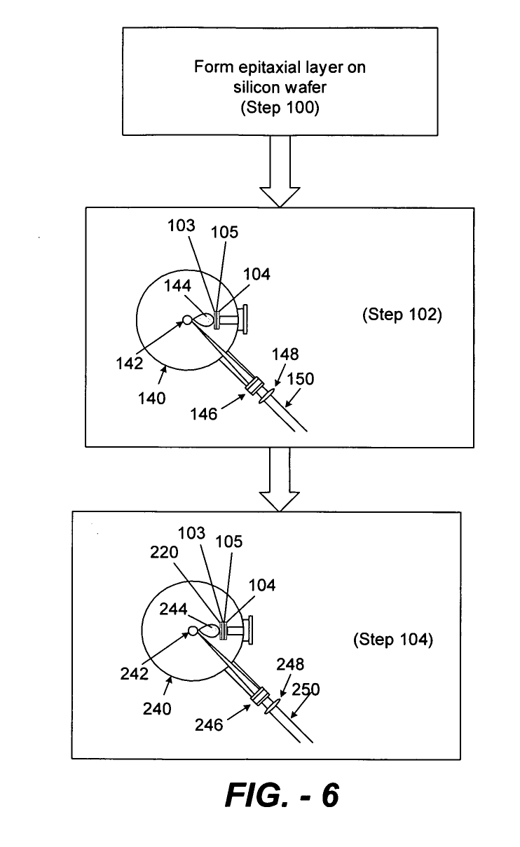

FIG. 6 is a simplified schematic flow diagram illustrating an embodiment of a method of forming a media in accordance with the present invention. The media comprises and can be subsequently built on a base layer and/or substrate of STO. Preferably, the STO layer is an epitaxial layer formed on a silicon wafer which silicon wafer is a substrate, although in other embodiments bulk STO is suitable. Forming STO on a silicon wafer can enable fabrication techniques using thin film processing equipment, which may be more easily accessible semiconductor processing equipment for fabrication of the media. Further, as described above, forming STO on a silicon wafer can simplify or improve integration with other components of a system for storing information, including MEMS components. STO can be formed as a single-crystal base layer 105 on a silicon wafer 104 using any number of fabrication techniques known in the art, for example PLD, MBE, MOCVD and others (Step 100). The STO-silicon wafer can then be positioned in a pulsed laser deposition chamber 140 including a Sr₂RuO₄ target 142, the chamber 140 and target 142 having been prepared for PLD processing. The STO-silicon wafer 104 is processed using PLD techniques to form an SRO layer 103 (Step 102). PLD processing includes focusing a laser beam 150 through a lens 148 and striking the target 142 through a window 146 sealing the chamber 140. The laser ablates the target 142 upon irradiation and creates a plasma plume 144 that reacts with the STO-silicon wafer under certain conditions. For example, SRO growth on STO can be achieved in the PLD chamber by processing the wafer using a recipe that specifies the following PLD chamber parameters: chamber pressure generally maintained at 100 mTorr with O₂ flow, substrate holder temperature maintained at about 700° C., and 90 mJ (at 15 Hz) of laser energy applied to the target. The SRO-STO-silicon wafer is then prepared for further processing. The SRO-STO-silicon wafer can be positioned within a second PLD chamber 240 having a PbZr_{0.2}Ti_{0.8}O₃ target 242, or alternatively the Sr₂RuO₄ target 142 of the first chamber 140 can replaced with a PbZr_{0.2}Ti_{0.8}O₃ target 242, and processed using PLD techniques to form a PZT recording layer 220 (Step 104). As above, PLD processing includes focusing a laser beam 250 through a lens 248 and striking the target 242 through a window 246 sealing the chamber 240. The laser ablates the target 242 upon irradiation and creates a plasma plume 244 that reacts with the SRO surface under certain conditions. For example, PZT growth on SRO can be achieved in the PLD chamber 240 by processing using a recipe that specifies the following PLD chamber parameters: chamber pressure generally maintained at 100 mTorr with O₂ flow, substrate holder temperature maintained at about 630° C., and 95 mJ (at 3 Hz) of laser energy applied to the target. It is noted that the chamber parameters given above are merely exemplary, and embodiments in accordance with present invention can include chamber parameters that vary relative to given chamber parameters.

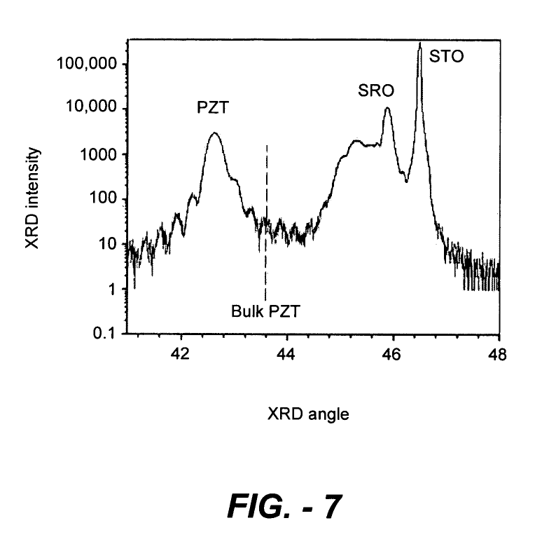

X-ray diffraction (XRD) techniques can be applied to characterize thickness, crystallographic structure, and strain in thin epitaxial films. Referring to FIG. 7, a plot of XRD results (i.e., a rocking curve) is illustrated for an embodiment of a media in accordance with the present invention comprising a PZT-SRO-STO-silicon film stack. As shown, the film stack has a first intensity peak corresponding to PZT at about 42.3° (2θ), the first intensity peak having a full width at half maximum (FWHM) value of about 0.129°, indicating a high degree of crystallinity. The intensity peak corresponds to a PZT layer has a c-lattice constant of about 0.4268 nm, longer than a c-lattice constant of bulk PZT of about 0.4148 nm. Unstrained, bulk PZT has an intensity peak at about 43.6° (2θ), measurably shifted to an increased XRD angle from the intensity peak of the tetragonally strained PZT layer, with a FWHM substantially larger (a PZT film having FWHM of 0.3° can be considered a marginal quality crystalline). Shifting of the XRD intensity peak position to a lower XRD angle has been associated with stretching of the out-of plane c-lattice constant. A series of satellite peaks on either side of the tetragonally strained PZT intensity peak are well-defined, further indicating a high degree of crystallinity (at least relative to bulk PZT) and layer surface quality (e.g., an atomically smooth surface). The series of satellite peaks is further indicative of a high degree of lattice matching at the PZT-SRO interface so that a high lattice constant ratio (i.e., a ratio of c-lattice constant to a-lattice constant describing tetragonality) can be deduced. It is noted that in addition to characteristics such as surface smoothness, the tetragonally strained ferroelectric material forms longer ferroelectric dipoles, benefiting faster bit writing, stronger (and better resolved) bit readout signal, and longer bit stability over time.

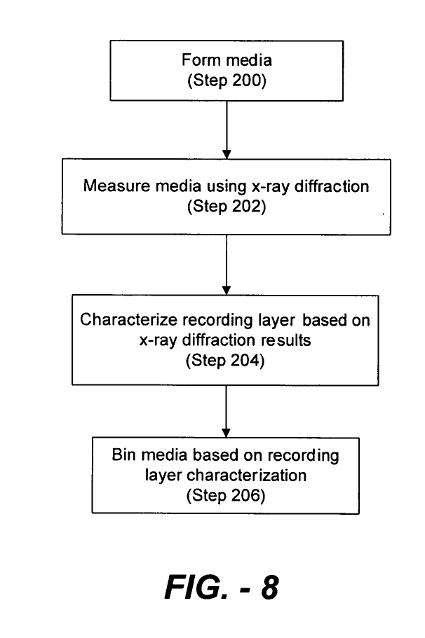

Referring to FIG. 8, embodiments of a method of binning a media and a method of fabricating a system for high density data storage in accordance with the present invention can apply fabrication and measurement techniques described herein. In an embodiment, a media can be formed, for example, as illustrated in FIG. 6 and described above (Step 200). Following epitaxial formation of the recording layer (e.g., PZT) the media can be measured using XRD techniques (Step 202). The intensity peak of the recording layer can be observed from the XRD results, allowing the recording layer to be characterized at least for c-lattice constant, degree of tetragonal strain, and degree of crystallinity (Step 204). As noted above, such characteristics (among others) can indicate a degree of smoothness and spontaneous polarization magnitude. A media's suitability for certain applications and/or media performance specifications may be determined based on such indications. For example, a high degree of smoothness can correspond to a maximum bit density of a media. Media may be binned for different maximum capacities based on estimated maximum bit density. A high degree of smoothness can also correspond to a maximum read and/or write speed. Binning can comprise subdividing the manufactured distribution for use in devices having different performance characteristics. Media may be binned for different maximum data transfer rates. Systems in accordance with the present invention can include programming to regulate system performance based on characteristics of the media.

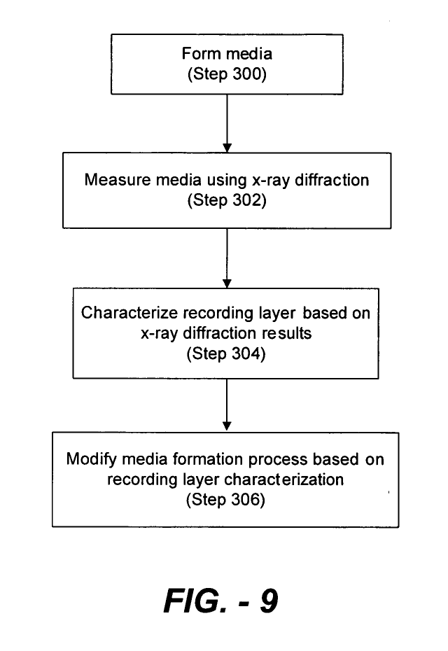

Referring to FIG. 9, embodiments of a method of monitoring manufacturing of a media in a system for high density data storage in accordance with the present invention apply measurement techniques described herein. In an embodiment, a media can be formed using manufacturing processes, for example, applying techniques as illustrated in FIG. 6 and described above (Step 300). Following epitaxial formation of the recording layer (e.g., PZT) the media can be measured using XRD techniques (Step 302). The intensity peak of the recording layer can be observed from the XRD results, allowing the recording layer to be characterized at least for c-lattice constant, degree of tetragonal strain, and degree of crystallinity (Step 304). The manufacturing processes for forming the media can be qualified based on characterization of the media. Thus, for example, where a targeted c-lattice constant of a PZT recording layer is 0.42395 nm, c-lattice determined to be 0.42 nm is length may indicate a process shift requiring adjustment in fabrication equipment, recipe, protocol, etc. Methods of monitoring manufacturing media in accordance with the present invention can provide benefits, such as higher throughput achieved by eliminating fabrication equipment qualification procedures that rely on measuring qualification dedicated structures, rather than usable product, and near in-situ monitoring to minimize yield loss when a manufacturing process drifts.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A media for storing information comprising:
a substrate;
a conductive layer formed over the substrate; and
a ferroelectric layer epitaxially formed on the conductive layer, the ferroelectric layer including:
an a-lattice constant that is substantially matched to an a-lattice constant of the conductive layer, and
an average c-lattice constant that is longer than an average c-lattice constant of a bulk-grown ferroelectric layer.

2. The media of claim 1, wherein:
the conductive layer is strontium ruthenate, and
the ferroelectric layer is lead zirconium titanate.

3. The media of claim 2, wherein the average c-lattice constant of the ferroelectric layer is larger than 0.42 nanometers.

4. The media of claim 2, wherein the substrate is strontium titanate.

5. The media of claim 2, wherein the substrate is single crystal silicon.

6. The media of claim 5, further comprising an epitaxial base layer formed between the substrate and the conductive layer, wherein the epitaxial base layer is strontium titanate.

7. A system for storing information, the system comprising:
a heteroepitaxial media including:
a substrate,
a base layer formed over the substrate,
a conductive layer formed on the base layer; and
a ferroelectric layer formed on the conductive layer, the ferroelectric film comprising:
an a-lattice constant that is lattice-matched to the conductive layer, and
an average c-lattice constant that is longer than an average c-lattice constant of a bulk-grown ferroelectric layer comprising the same chemical compound as the ferroelectric layer;
a cantilever;
a tip extending from the cantilever toward the heteroepitaxial media;
wherein the tip is adapted to apply a probe voltage to the ferroelectric layer;
a capacitive sensor formed over the cantilever;
wherein the capacitive sensor vibrates according to a response of the ferroelectric layer to the probe voltage; and
circuitry that can determine a polarization of the ferroelectric layer based on the vibration of the capacitive sensor.

8. The media of claim 7, wherein:
the base layer is strontium ruthenate, and
the ferroelectric layer is lead zirconium titanate.

9. The media of claim 8, wherein the average c-lattice constant of the ferroelectric layer is larger than 0.42 nanometers.

10. The media of claim 8, wherein the substrate is strontium titanate.

11. The media of claim 8, wherein the substrate is single crystal silicon.

12. A method of forming a media comprising:
forming an epitaxial layer of strontium titanate on a silicon wafer;
forming a layer of strontium ruthenate on the epitaxial layer of strontium titanate so that the strontium ruthenate is lattice matched to the epitaxial layer of strontium titanate; and
forming a layer lead zirconate titanate on the layer of strontium ruthenate so that the lead zirconate titanate is lattice matched to the layer of strontium ruthenate;
wherein the lead zirconate titanate is tetragonally strained.
